(19) United States
(12) Patent Application Publication
(10) Pub. No.: US 2017/0033058 A1
(43) Pub. Date: Feb. 2, 2017

(54) STRUCTURES AND METHODS FOR SEMICONDUCTOR PACKAGING

(71) Applicant: Everspin Technologies, Inc., Chandler, AZ (US)

(72) Inventors: Quan Bang LI, Gilbert, AZ (US); ChingTi LIANG, Chandler, AZ (US)

(73) Assignee: Everspin Technologies, Inc., Chandler, AZ (US)

(21) Appl. No.: 15/222,260

(22) Filed: Jul. 28, 2016

Related U.S. Application Data
(60) Provisional application No. 62/199,613, filed on Jul. 31, 2015.
(60) Provisional application No. 62/208,153, filed on Aug. 21, 2015.

(51) Int. Cl. H01L 23/00; H01L 23/495; H01L 23/31

(52) U.S. Cl. CPC H01L 23/564; H01L 23/3107; H01L 23/49524; H01L 23/49582

(57) ABSTRACT

A semiconductor package including a lead frame having a die pad and a plurality of leads arranged along at least a portion of a periphery of the semiconductor package, a semiconductor die secured to the die pad, wherein at least a portion of the semiconductor die extends beyond a periphery of the die pad, and a molding material encapsulating the semiconductor die and at least a portion of the die pad.

### CROSS-REFERENCE TO RELATED APPLICATIONS

This application claims the benefits of priority from U.S. Provisional Application No. 62/199,613, filed on Jul. 31, 2015, and U.S. Provisional Application No. 62/208,153, filed on Aug. 21, 2015, both of which are incorporated by reference herein in their entireties.

### TECHNICAL FIELD

The present disclosure relates to packaging of a semiconductor device. More specifically, the present disclosure relates to lead frame based packaging of a semiconductor device.

### INTRODUCTION

A semiconductor package is a metal, plastic, glass and/or ceramic casing containing one or more semiconductor electronic components. Typically, individual discrete integrated circuit (IC) electronic components are etched in a silicon (or another semiconductor material) wafer before being cut and assembled in a package. The package provides protection against mechanical damage and corrosion, holds the contact pins or leads that are used to connect the IC device (“die”) to external circuits, and assists in dissipating the heat produced by the device. A large number of package types exist in the industry. In some of these packages, a lead frame is used to electrically connect terminals (or electrical contacts) of the die to external circuits. A lead frame is a metal structure inside a package that carries signals from the die to the external circuits. In typical lead frame based packages, the die is typically attached (using adhesives, etc.) to a surface of the lead frame (e.g., die attach pad or “die pad”), and bond wires attach the terminals of the die to leads of the lead frame. The die, lead frame, and the bond wires then may be encapsulated using a molding material or a plastic material to form a case with the die and portions of the lead frame encapsulated therein, and with the ends of the leads exposed on the periphery of the case. These exposed leads then are connected (e.g., bonded, soldered, etc.) to the corresponding terminals of an external circuit (e.g., a printed circuit board (PCB)).

In some lead frame based semiconductor packages (e.g., quad-flat no-leads (QFN), dual-flat no-leads (DFN), etc.), a back side of the die pad (opposite the surface where the die is attached) may be exposed. When the package is attached to the PCB, the exposed die pad region of the package may improve heat transfer out of the package (e.g., into the PCB). In some packages (SOP, TSOP, etc.), the die pad region of the lead frame may be encapsulated by, or embedded within, the plastic material of the package. In typical packages, the die pad may be larger than the semiconductor die due to traditional semiconductor package manufacturing processes. However, in some applications, a larger die pad area is not desirable since it increases package size.

### BRIEF DESCRIPTION OF THE DRAWINGS

In the course of the detailed description to follow, reference will be made to the attached drawings. The drawings show different aspects of the present disclosure and, where appropriate, reference numerals illustrating like structures, components, materials and/or elements in different figures are labeled similarly. It is understood that various combinations of the structures, components, and/or elements, other than those specifically shown, are contemplated and are within the scope of the present disclosure.

Moreover, there are many embodiments of the present disclosure described and illustrated herein. The present disclosure is neither limited to any single aspect nor embodiment thereof, nor to any combinations and/or permutations of such aspects and/or embodiments. Moreover, each of the aspects of the present disclosure, and/or embodiments thereof, may be employed alone or in combination with one or more of the other aspects of the present disclosure and/or embodiments thereof. For the sake of brevity, certain permutations and combinations are not discussed and/or illustrated separately herein.

FIG. 1 illustrates a cut-away view of an exemplary semiconductor package of the current disclosure;

FIG. 2 illustrates a cross-section view of another exemplary semiconductor package of the current disclosure;

FIG. 3 illustrates a cross-section view of another exemplary semiconductor package of the current disclosure;

FIG. 4 illustrates a bottom view of an exemplary semiconductor package of the current disclosure;

FIG. 5 illustrates a cross-section view of another exemplary semiconductor package of the current disclosure;

FIG. 6 illustrates a flowchart of an exemplary fabrication process for producing a semiconductor package of the current disclosure; and

FIG. 7 depicts an array of exemplary semiconductor packages of the current disclosure.

Again, there are many embodiments described and illustrated herein. The present disclosure is neither limited to any single aspect nor embodiment thereof, nor to any combinations and/or permutations of such aspects and/or embodiments. Each of the aspects of the present disclosure, and/or embodiments thereof, may be employed alone or in combination with one or more of the other aspects of the present disclosure and/or embodiments thereof. For the sake of brevity, many of those combinations and permutations are not discussed separately herein.

As used herein, the terms “comprises,” “comprising,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. The term “exemplary” is used in the sense of “example,” rather than “ideal.”

### DETAILED DESCRIPTION

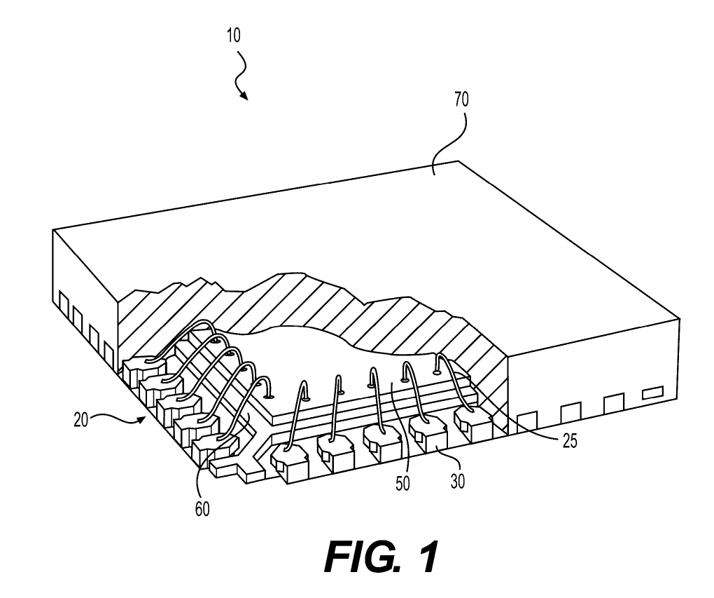

FIG. 1 illustrates an exemplary lead frame based semiconductor package 10 of the current disclosure. Package 10 may include a semiconductor IC die 50 attached to a die pad 60 of a lead frame 20. The die 50 may be attached to the die pad 60 by any known method. In some embodiments, an adhesive die attach material may be used to attach a back side (i.e., a surface of the die 50 opposite the front side where integrated circuits are formed by IC fabrication techniques) of the die 50 to a surface of the die pad 60. In some embodiments, a die attach film (DAF) may be used to attach or otherwise secure the die 50 to the die pad 60. A plurality of interconnects 25 (e.g., wires) may connect electrical contacts (or terminals) of the die 50 to leads 30 of the lead frame 20. Any suitable technique (e.g., a wire bonding) may be used to electrically connect the die 50 to the leads 30. Typical wire bonding techniques employ some combination of heat, pressure, and/or ultrasonic energy to make a weld. The die 50 and the lead frame 20 may then be encapsulated with a molding material 70 (e.g., a plastic or suitable (e.g., insulating material) using a molding process. Since wire bonding and encapsulation techniques are well known in the art, they are not discussed further herein.

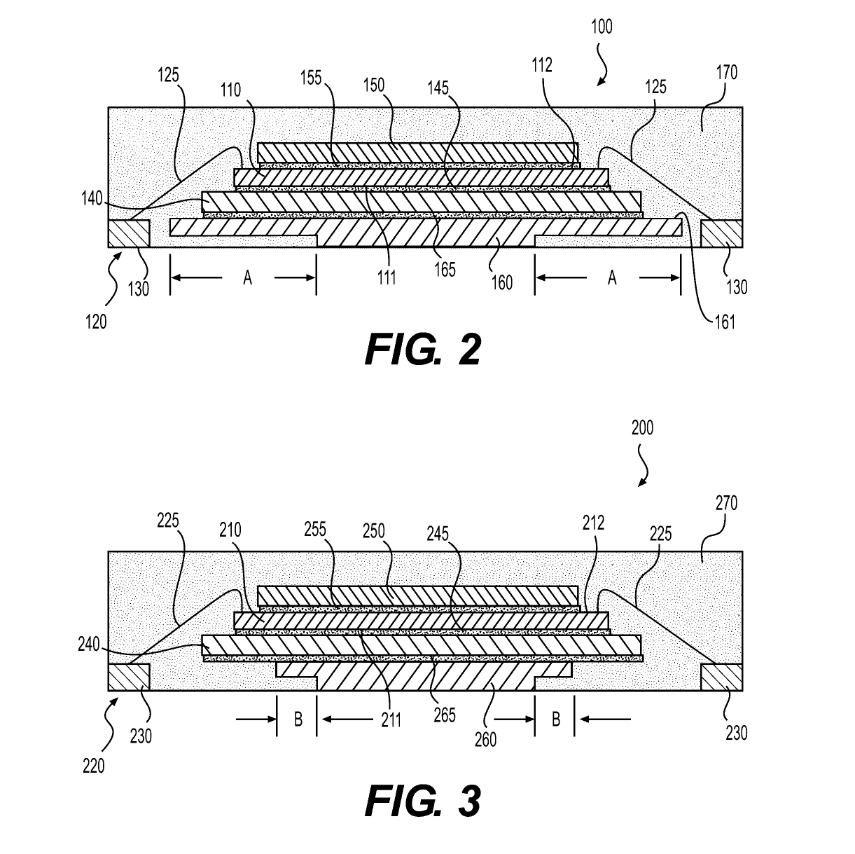

FIG. 2 illustrates a cross-sectional view of an exemplary lead frame based package 100 implemented for an exemplary magnetoresistive semiconductor device. The magnetoresistive semiconductor die 110 of package 100 may include an underlying magnetically sensitive circuit. The die 110 may be sensitive to internally induced magnetic fields and external magnetic fields. For example, the die 110 may be a magnetoresistive memory device having an array of magnetic memory cells, such as an MRAM chip having an array of spin torque and/or magnetic tunnel junction (“MTJ”) bits (not shown). Metal shields (e.g., top and bottom shields 150, 140) may be positioned on the front and back sides of the die 110 to protect its electrical circuits from external magnetic fields, and external devices (e.g., on the PCB) from any internal magnetic fields generated by die 110. The die pad 160 of the lead frame 120 of package 100 also may be modified to provide a relatively reduced exposed area of the pad 160. In some embodiments, as illustrated in FIG. 2, the thickness of a length (and/or width) of the die pad 160 along the periphery of the die pad 160 may be reduced by etching (or any other suitable process) to reduce the exposed area of the pad 160. The die pad 160 and/or the exposed area of a die pad 160 may include any suitable configuration, dimension, or shape. In some embodiments, a length corresponding to about one half the length “A” of the die pad 160 (one half-etched or “½-etched” area) may be thinned along the periphery of the die pad, as shown in FIG. 2.

As illustrated in FIG. 2, the bottom shield 140 may be attached to (e.g., glued to, deposited on, etc.) a planar surface 161 of the die pad 160, and the first surface 111 (or back side) of the die 110 may be attached to the bottom shield 140. The top shield 150 may be attached to the second surface 112 (front side) of the die 110, and the plurality of interconnects 125 may electrically connect contacts or terminals (not shown) of the die 110 to the plurality of leads 130 or terminals of the lead frame 120. Some or all of these leads 130 may be electrically isolated from the die pad 160 to prevent shorting. As shown in FIG. 2, an area of surface 161 of die pad 160 may be greater than the area of a respective opposing surfaces of bottom shield 140, semiconductor die 110, and top shield 150. In some embodiments, the half-etched length “A” of the die pad 160 may be larger than about 0.1 mm +/− 0.05 mm. In some embodiments, the half-etched length “A” of the die pad 160 may be larger than about 0.15 mm. Due to the requirement of foot print compatibility of the package, a large die pad, such as a die pad 160 of FIG. 2, may require a relatively large half-etched area to reduce the exposed area of the pad. The relatively large recess resulting from a large half-etched length “A” may present difficulties for the mold compound flow during the molding process. In some applications, an expensive molding tool or molding process may be required to remedy this deficiency. Reducing the overall size or area of die pad 160 may provide a smaller exposed area of the die pad 160 while the length required for half-etching may be reduced so as to meet a predetermined molding requirement.

In some embodiments of the current disclosure, an area of the die pad of a semiconductor package is smaller than an area of the die pad. The smaller die pad area presents minimal risk to package integrity as compared to a package with a large die pad in terms of coefficient of thermal expansion mismatch induced thermal stresses.

For example, FIG. 3 illustrates a cross-section view of another exemplary embodiment of a lead frame based package 200 of the present disclosure. In package 200, a magnetoresistive semiconductor die 210 (e.g., an MRAM chip) may be sandwiched on its front and back sides by top and bottom shields 250, 240, and a plurality of interconnects 225 may electrically connect the die 210 to a plurality of leads 230 of the lead frame 220. As described with reference to the embodiment of FIG. 2, the bottom shield 240 may be attached or otherwise secured to (e.g., glued to, deposited on, etc.) the die pad 260. Particularly, the back side (first surface 211) of the die 210 may be attached to an opposite surface of the bottom shield 240. The front side (second surface 212) of the die 210 may then be attached to the top shield 250. As illustrated in FIG. 3, in some embodiments of package 200, an area of surface 265 of die pad 260 may be smaller than an overall area of bottom shield 240, die 210, and/or top shield 250. Generally, in embodiments of the current disclosure, the surface 265 of die pad 260 may include a smaller length and/or width as compared to the bottom and top shields 240, 250, and/or the die 210, regardless of the relative dimensions between the die pad 260, bottom shield 240, and top shield 250. In some embodiments, a length “B” of the half-etched portion of die pad 260 may be about 0.15 mm.

Although the use of both a top and bottom shield are described in the embodiments of FIGS. 2 and 3, this is only exemplary. In some embodiments, only a bottom shield or a top shield may be provided. Further, in some embodiments, the shields may be omitted. For example, it is contemplated that in some embodiments using a magnetoresistive die, a shield material may be deposited on, or otherwise provided directly on, the front and/or back sides of the die 210. In general, the top and bottom shield (if any) may have any suitable shape and configuration (square, rectangular, round, etc.). In some embodiments, the top and/or bottom shield may have one or more cutouts.

Bottom shield 240 and top shield 250 may be formed of a metal having a relatively high magnetic permeability. One such high magnetic permeability metal is a nickel-iron alloy, such as the commercially available Mu-metal®. The high permeability metal may be effective at screening and/or filtering static or low-frequency magnetic fields. High permeability metal may be provided in a sheet or foil format which may be readily fabricated into bottom shield 240 and top shield 250, and then adhered to die 210 utilizing a suitable adhesive. Although nickel-iron alloy is discussed herein, it should be understood that other materials having relatively high permeability and that do not retain their magnetization upon the removal of a magnetic field may be used. Additionally, and/or alternatively, bottom shield 240 and top shield 250 may be a soft magnetic material in some embodiments. In some embodiments, bottom shield 240 and/or top shield 250 may be fabricated to a desired dimension utilizing a chemical process (e.g., photolithography and etching). Alternatively, a mechanical process (stamping, machining, etc.) may be employed to fabricate bottom shield 240 and/or top shield 250 to a desired dimension.

In some embodiments, an adhesive may be used to attach the shields to the die and the die pad. In one embodiment, an adhesive 265 may attach the bottom shield 240 to the die pad 260, and an adhesive 245 may attach the die 210 to the bottom shield 240. Additionally, and/or alternatively, an adhesive 255 may attach the top shield 250 to the die 210. Adhesives 245, 255, and 265 may be similar to, or different from, one another. In general, any type of adhesive may be used. In one embodiment, the adhesives 245, 255, and 265 may be an electrically non-conductive paste and/or adhesive film. In some embodiments, one or more of the adhesives may be electrically and/or thermally conductive. In embodiments where the adhesive is an epoxy, the epoxy may be dispensed between the adherents in any manner (e.g., screen printed, needle deposited, etc.). In some embodiments, one or more of adhesives 245, 255, and 265 may be a B-Stage DAF tape and/or a direct epoxy die attach, or any suitable combination thereof.

Any type of lead frame 120, 220 may be used in packages 100, 200 of the current disclosure. The lead frames 120, 220 may be made of any electrically conductive material and may be formed by any known process (e.g., punching, etching, stamping, etc.). In some embodiments, the lead frame may be made of one or more of copper, a copper alloy, iron, and/or an iron alloy. The die pads 160, 260 of lead frame 120, 220 may have any shape and configuration. In some embodiments, the die pad may include a main portion and a peripheral portion. The main portion may have a thickness greater than the peripheral portion. The thinner peripheral portions may be formed by any known process. In some embodiments, material at the periphery of the die pad 160, 260 may be removed by a chemical (e.g., etching, etc.) or a mechanical (e.g., machining) process to create a thinner peripheral portion. It is also contemplated that, in some embodiments, the lead frame will be manufactured with a thinner peripheral region. In FIG. 2, e.g., the peripheral portion is shown by arrows “A,” and in FIG. 3, e.g., the peripheral portion is shown by arrows “B.” The die pad 160, 260 may have any shape. The thinner peripheral portions of the die pad 160, 260 may serve as a locking feature for the mold compound after the molding process. For example, during molding, the mold material may flow into the recess formed below the thinner peripheral portion and “lock-in” the molding compound around the die pad 160, 260. Although a thinner peripheral portion is only illustrated and described with reference to the die pad 160, 260, it is also contemplated that other features of the lead frames 120, 220 (for example, leads 130, 230) may also have a thinner peripheral portion to lock-in the molding compound around these features. Additionally or alternatively, other features (protrusions, roughened surface, etc.) on all or selected portions of the lead frame may serve as locking features for the mold compound.

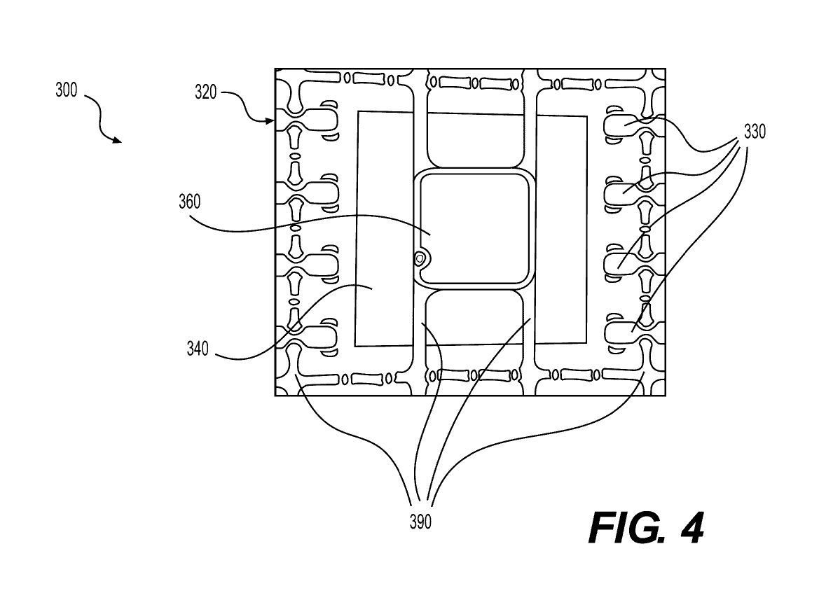

FIG. 4 illustrates a bottom view of an exemplary partially processed package (e.g., a dual flat no-lead (DFN) package) 300 of the current disclosure. Package 300 may utilize, e.g., a copper based lead frame 320 in which a pattern representing leads and die pad are etched. As shown in FIG. 4, the partially processed package 300 may include leads 330, tie bars 390, and a die pad 360 arranged to aid in the positioning of a bottom shield 340 and to aid in the locking-in of a suitable molding compound. For example, the leads 330 and/or the die pad 360 may include thinner peripheral portions (formed by, e.g., selectively half etching or otherwise removing portions of the bottom side of a lead and/or die pad) to serve as locking features for the molding compound. This may provide for a lead 330 and/or a die pad 360 structure having a top portion (encapsulated portion facing the die) larger or wider than a bottom, exposed portion. When encapsulated with a molding compound, the reduced thickness periphery of the die pad 360 may serve as a mold locking feature and improve integrity of the semiconductor package 300.

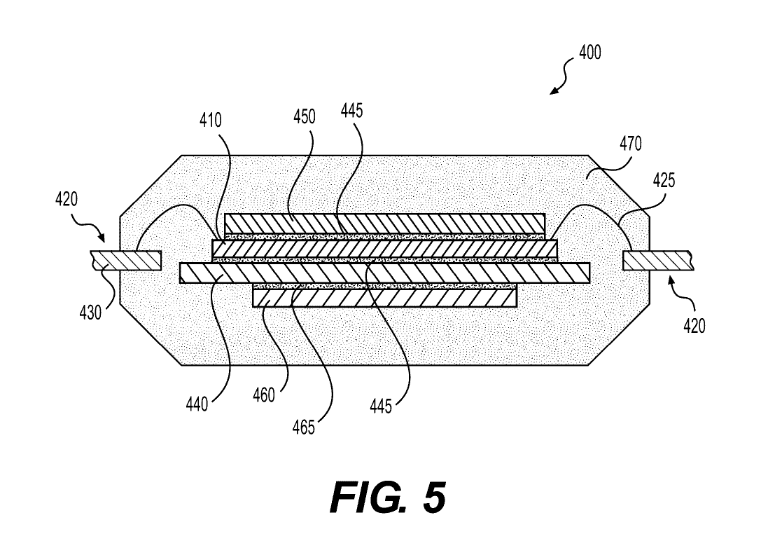

Although the embodiments of the packages 100, 200, 300 illustrated in FIGS. 2-4 depict a die pad 160, 260, 360 which is exposed on the back side of the package, this is not a limitation. In general, the current disclosure can be applied to any type of package (e.g., TSOP/SOP and SOIC packages) by making the die pad to which the die (and/or the shield) is attached smaller than the die (and/or the shield) in the package. FIG. 5 illustrates an exemplary embodiment of a lead frame based package 400 in which the die pad 460 is embedded within, and enclosed by, the plastic molding compound 470 of package 400. As illustrated in FIG. 5, the die pad 460 of lead frame 420 may have a smaller overall area than the die 410 of package 400. Any type of die (including a magnetoresistive die) may be packaged using package 400. As described with reference to the embodiments of FIGS. 2 and 3, the die 410 may be sandwiched between a top shield 450 and a bottom shield 440, and the bottom shield 440 may be attached to the die pad 460. The die pad 460 also may include a smaller overall area as compared to shields 440 and 450. Interconnects 425 may electrically connect the die 410 to the leads 430 of the lead frame 420, and adhesives 445, 455, and 465 may be used to secure the die 410, the shields 440, 450, and/or the die pad 460 together. Although FIG. 5 illustrates a die pad 460 having the same thickness throughout its area, as discussed with reference to FIGS. 2 and 3, in some embodiments, the die pad 460 may include locking features to promote better attachment with the molding compound. For instance, in some embodiments, portions of the lead frame 420, including the die pad 460, may include a textured surface (roughened, etc.) to enhance adhesion of the molding compound to the lead frame 420. In some embodiments, a region of the die pad 460 along one or more peripheries may have a reduced thickness to form a recess/opening/cavity into which the molding compound can flow in to lock-in the molding compound around the package 300.

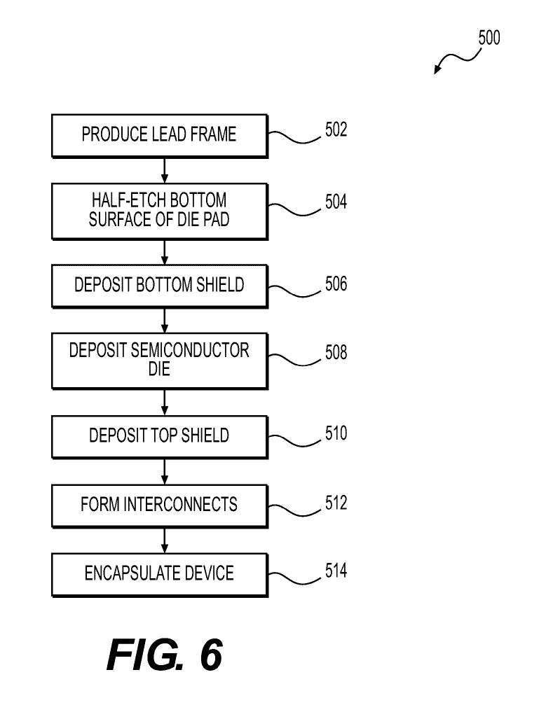

FIG. 6 illustrates an exemplary manufacturing process 500 for the semiconductor packages of the current disclosure. At step 502, a lead frame may be provided through known manufacturing methods such as punching and/or etching. The lead frame may include a die pad, leads, and/or tie bars. Then, at step 504, a peripheral region of the bottom surface of a die pad is thinned by a chemical (etching, etc.) or a mechanical (machining, etc.) process (e.g., half-etched as shown by arrows A and B of FIGS. 2 and 3, respectively) to serve as locking features after molding. At step 506, a bottom shield may be attached to the etched die pad using an adhesive (e.g., epoxy adhesive (165, 265), B-stage DAF tape, etc.). To attach the bottom shield, the adhesive may be placed on a surface of the bottom shield, and the adhesive covered surface pressed against the non-etched side of the die pad. Alternatively, or additionally, the adhesive may be placed on the non-etched side of the die pad, and the bottom shield may be pressed against the die pad. Those of ordinary skill will readily recognize that a bottom shield may be omitted from process 500.

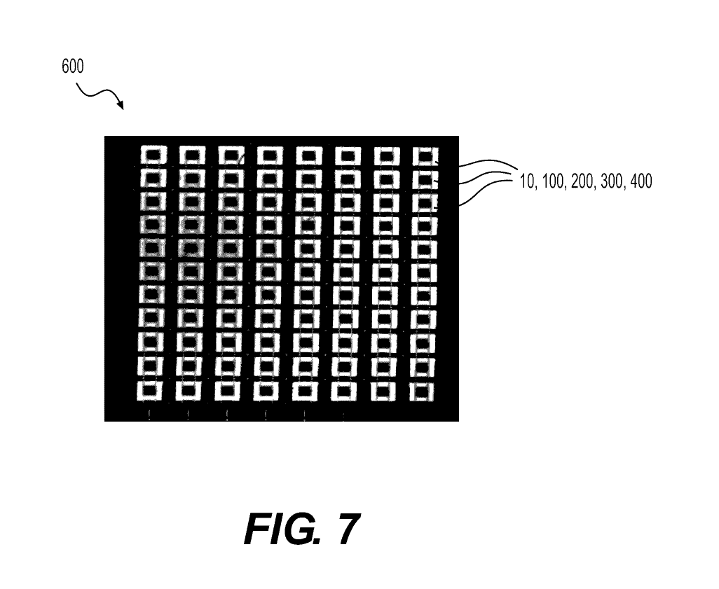

At step 508, a semiconductor die, such as semiconductor die (110, 210, 410) may be attached to the bottom shield (or, to die the pad if a bottom shield is omitted) using an adhesive, such as a B-stage DAF tape, as disclosed above. To attach the die to the bottom shield (or die pad), an adhesive (such as adhesives 145 and 245) may be deposited on a back side (surface opposite the surface with circuits) of the die and/or the bottom shield and the two surfaces pressed against each other. At step 510, a top shield (150, 250, 450) may be similarly attached to the front side (surface with circuits) of the die using an adhesive (such as a B-stage DAF tape, adhesives 155, 255, etc.). Again, a top shield may be omitted from process 500. At step 512, a plurality of interconnects, such as interconnects (125, 225, 425) may be formed to electrically connect the contacts of the semiconductor die to the leads of the lead frame. At step 514, a molding compound, (170 and 270) may be used to encapsulate the top shield (if provided), the semiconductor die, the bottom shield (if provided), interconnects, and leads using a suitable molding process (e.g., vacuum molding). The molded package may then be cured to form an array 600 of packages, as illustrated in FIG. 7.

Of course, other fabrication processes may subsequently occur. For example, the encapsulated packages may be subjected to a lead finishing process to clean and finish the leads and/or singulated to form individual packages. These packages may then be subjected to testing (e.g., burn-in tests, electrical tests, etc.), marking, and inspection.

Although various embodiments of the present disclosure have been illustrated and described in detail, it will be readily apparent to those skilled in the art that various modifications may be made without departing from the present disclosure or from the scope of the appended claims.

We claim:

1. A semiconductor package, comprising:
a lead frame having a die pad and a plurality of leads arranged along at least a portion of a periphery of the semiconductor package;
a semiconductor die secured to the die pad, wherein at least a portion of the semiconductor die extends beyond a periphery of the die pad; and
a molding material encapsulating the semiconductor die and at least a portion of the die pad.

2. The semiconductor package of claim 1, wherein an entirety of the die pad is encapsulated within the molding material.

3. The semiconductor package of claim 1, wherein a surface of the die pad is not covered by the molding material.

4. The semiconductor package of claim 1, wherein the die pad is located in a center of the semiconductor package.

5. The semiconductor package of claim 1, further comprising:
a magnetic shield disposed between the die pad and the semiconductor die.

6. The semiconductor package of claim 1, further comprising:
a first magnetic shield disposed adjacent a first surface of the semiconductor die; and
a second magnetic shield disposed adjacent a second surface of the semiconductor die, wherein the second surface is opposite the first surface.

7. The semiconductor package of claim 1, further comprising a plurality of magnetic shields.

8. The semiconductor package of claim 7, wherein a length and a width of a surface at least one magnetic shield are larger than a length and a width of a corresponding surface of the die pad.

9. The semiconductor package of claim 1, wherein at least one lead of the plurality of leads is exposed.

10. The semiconductor package of claim 1, wherein a length and a width of a surface of the semiconductor die are larger than a length and a width of a corresponding surface of the die pad.

11. The semiconductor package of claim 1, wherein an area of the die pad is smaller than an area of the semiconductor die.

12. The semiconductor package of claim 7, wherein an area of the die pad is smaller than an area of at least one magnetic shield of the plurality of magnetic shields.

13. The semiconductor package of claim 7, wherein at least one magnetic shield of the plurality of magnetic shields is made of a nickel iron alloy.

14. The semiconductor package of claim 1, wherein the semiconductor die includes a magnetoresistive device.

15. A semiconductor package, comprising:
a lead frame having a die pad and at least one lead exposed beyond the semiconductor package, wherein the die pad defines a first area;
a first magnetic shield secured to the die pad, wherein the first magnetic shield defines a second area;
a semiconductor die secured to the first magnetic shield, wherein the semiconductor die defines a third area;
a second magnetic shield secured to the semiconductor die, wherein the second magnetic shield defines a fourth area; and
a molding material encapsulating the semiconductor die and at least a portion of the die pad,
wherein the first area is smaller than each of the second, third, and fourth areas.

16. The semiconductor package of claim 15, wherein at least one of the first and second magnetic shields comprises nickel or iron.

17. The semiconductor package of claim 15, wherein an entirety of the die pad is encapsulated within the molding material.

18. The semiconductor package of claim 15, wherein a surface of the die pad is not covered by the molding material.

19. The semiconductor package of claim 18, wherein the surface of the die pad defines a fifth area, and the fifth area is smaller than each of the first, second, third, and fourth areas.

20. The semiconductor package of claim 15, wherein the semiconductor die includes a magnetoresistive device.
